(19) United States
(12) Patent Application Publication
(10) Pub. No.: US 2016/0043741 A1
(43) Pub. Date: Feb. 11, 2016

(54) CODING METHOD AND DEVICE

(71) Applicants: SK hynix Inc., Gyeonggi-do (KR); Korea Advanced Institute of Science and Technology, Daejeon (KR)

(72) Inventors: Dae-Sung KIM, Gwangju (KR); Jeong-Seok HA, Daejeon (KR)

(21) Appl. No.: 14/546,685

(22) Filed: Nov. 18, 2014

(30) Foreign Application Priority Data
Aug. 6, 2014 (KR) 10-2014-0100995

(51) Int. Cl. H03M 13/29; H03M 13/15

(52) U.S. Cl. CPC H03M 13/2906; H03M 13/1515; H03M 13/152

(57) ABSTRACT

An encoding method includes generating a plurality of parity blocks by encoding a plurality of messages through an external code; generating a plurality of message data by combining the plurality of messages and the plurality of parity blocks; and generating a plurality of symbols by encoding each of the plurality of message data through an internal code.

### CROSS-REFERENCE TO RELATED APPLICATIONS

The present application claims priority of Korean Patent Application No. 10-2014-0100995, filed on Aug. 6, 2014 which is incorporated herein by reference in its entirety.

### BACKGROUND

1. Field

Exemplary embodiments of the present invention relate to a coding method and device, and more particularly, to a coding method and device with improved message protection.

2. Description of the Related Art

Conventionally, messages have been protected by units of access.

For example, when access is performed on a page basis, a single page message may be divided into a plurality of blocks, and a BC-BCH code may be applied to each of the blocks.

In the conventional method, the basis for message protection is limited to the single unit of access. Thus, the message protection level may be limited.

### SUMMARY

Various embodiments are directed to a coding method and a device capable of providing protection on a message by a single unit of access as well as by a plurality of units of access, thereby improving message protection.

In an embodiment, an encoding method may include: generating a plurality of parity blocks by encoding a plurality of messages through an external code; generating a plurality of message data by combining the plurality of messages and the plurality of parity blocks; and generating a plurality of symbols by encoding each of the plurality of message data through an internal code.

In an embodiment, a decoding method for decoding a first symbol may include: decoding the first symbol through an internal code; decoding a second symbol through the internal code when the first symbol has an error; and correcting errors that the first and second symbols have through an external code.

In an embodiment, an encoding device may include: a parity generation unit suitable for generating a plurality of parity blocks by encoding a plurality of messages through an external code; and an internal encoder suitable for generating a plurality of message data by combining the plurality of messages and the plurality of parity blocks, and generating a plurality of symbols by encoding each of the plurality of message data through an internal code.

In an embodiment, a decoding device for decoding a first symbol including an external code may include: an internal decoder suitable for decoding the first symbol and a second symbol through an internal code; a message generation unit suitable for generating an operation message by logically combining first and second messages, wherein the first message is generated through decoding of the first symbol and the second message is generated through the decoding of the second symbol; and an external decoder suitable for correcting errors that the first and second messages of the first and second symbols have through the external code.

### BRIEF DESCRIPTION OF THE DRAWINGS

FIG. 1 is a flowchart illustrating an encoding method in accordance with an embodiment of the present invention.

FIGS. 2 to 6 are diagrams illustrating a message being encoded by an encoding method shown in FIG. 1.

FIGS. 7 and 8 are flowcharts illustrating a decoding method in accordance with an embodiment of the present invention.

FIG. 9 is a diagram illustrating operation message blocks generated through step S310 shown in FIG. 8.

FIG. 10 is a block diagram illustrating an encoding device in accordance with an embodiment of the present invention.

FIG. 11 is a block diagram illustrating an encoding device in accordance with another embodiment of the present invention.

FIG. 12 is a block diagram illustrating a decoding device in accordance with an embodiment of the present invention.

FIG. 13 is a simulation graph illustrating a result in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In the following description, it is assumed that the unit of access is a single page. A code used for protecting messages within the unit of access or a page is referred to as an internal code. A code used for protection of messages among a plurality of units of access or a plurality of pages is referred to as an external code. It will be assumed that the external code is applied among four pages.

In the following description, BC-BCH (Block-wise Concatenated Bose-Chaudhuri-Hocquenghem) code is exemplarily used as the internal code, and RS (Reed-Solomon) code is exemplarily used as the external code. The BC-BCH code and the RS code are well known to those skilled in the art.

Types of the internal and external codes and the number of pages to which the external code is applied may vary according to design.

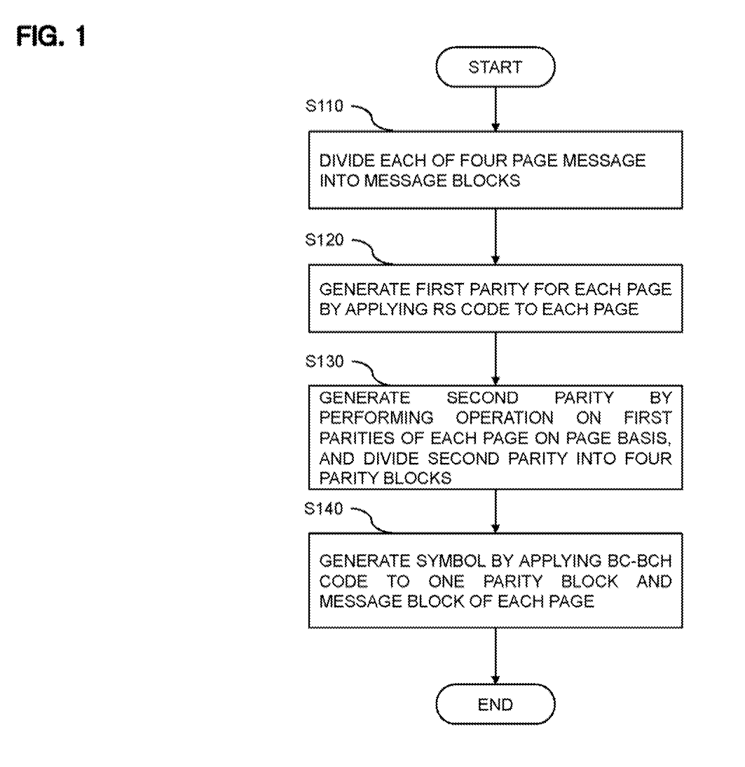

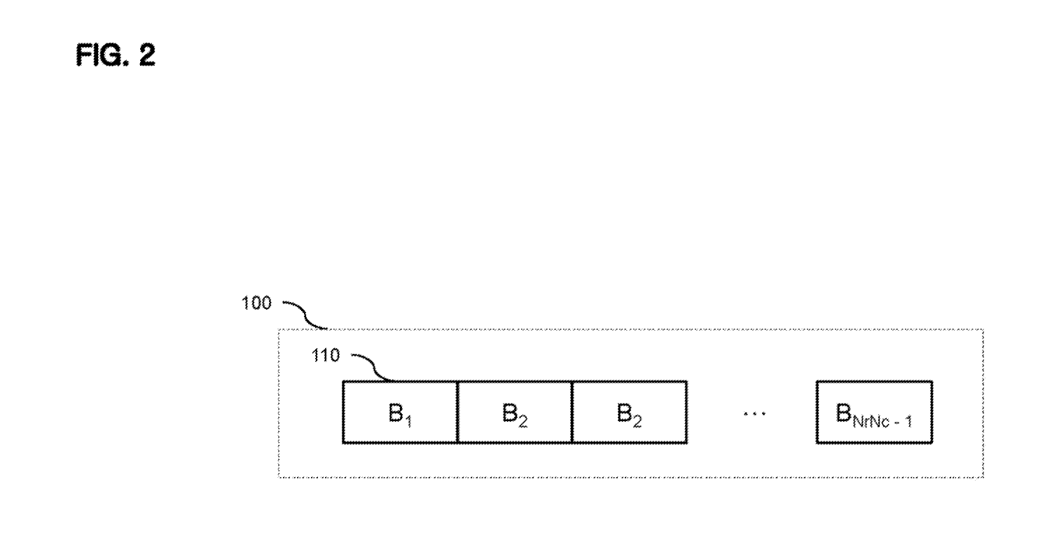

FIG. 1 is a flowchart illustrating an encoding method in accordance with an embodiment of the present invention. FIGS. 2 to 6 are diagrams illustrating a message being encoded by an encoding method shown in FIG. 1.

Referring to FIG. 1, the encoding method may divide each of four page messages into a plurality of message blocks at step S110.

FIG. 2 exemplarily illustrates a single page message 100 divided into a plurality of message blocks 110.

In FIG. 2, when the message blocks are arranged on row and column bases in order to apply the BC-BCH code, Nr and Nc represent the number of rows and columns, respectively.

The number of bits included in each of the message blocks 110, that is, the size of the message block may vary depending on the design of the BC-BCH code. For example, the message blocks 110 may have the same size or different sizes. In the latter case, the size of the message blocks may be designed such that the difference between the maximum size and the minimum size is set to 1. Hereafter, the maximum size of the message block 110 may be L.

When encoding is performed according to the RS code, the maximum size of each message block 110 may be limited. In this case, the message block 110 may be divided into a plurality of sub-message blocks 111, and encoding may then be performed through the RS code.

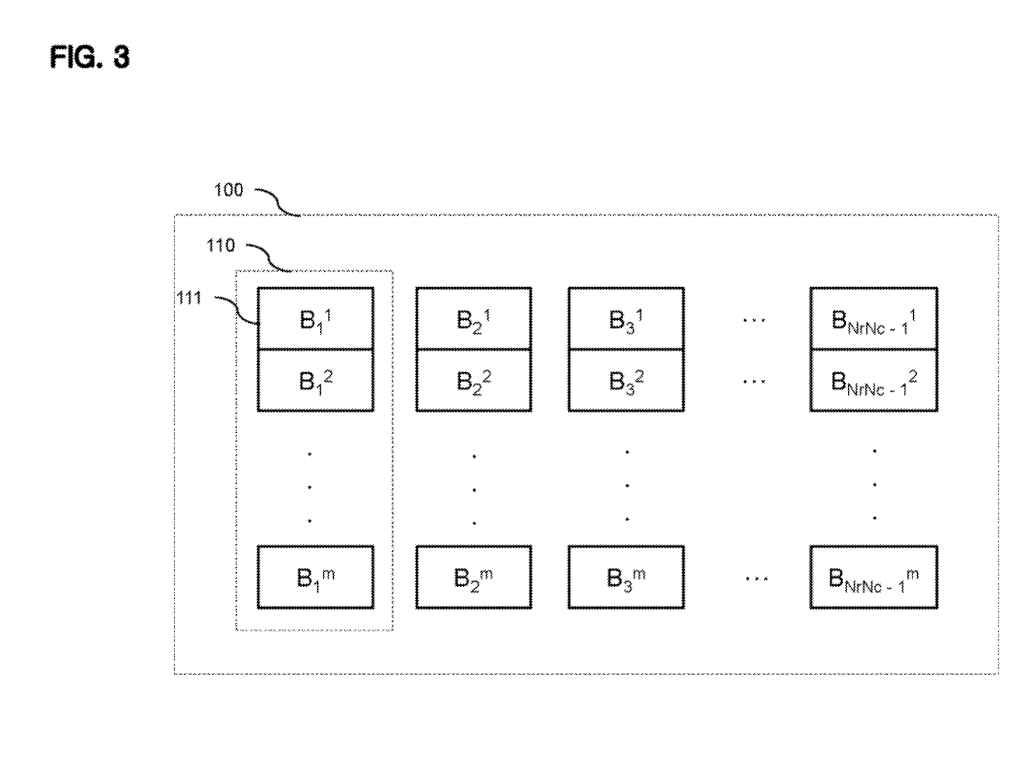

FIG. 3 exemplarily illustrates a single message block 110 divided into a plurality of sub-blocks 111.

In FIG. 3, each message block 110 may be divided into m number of sub-message blocks 111. When the size of one sub-message block 111 is represented by μ, and length of the message is L, the number of the sub-message blocks 111 is equal to m, as defined in Equation 1 below.

$$m = ⌈ \frac{L}{μ} ⌉ \qquad [ Equation 1 ]$$

Referring back to FIG. 1, the encoding method may generate a first parity 200 for each page according to the RS code at step S120 after the page is divided into the message blocks 110 or the sub-message blocks 111 at step S110.

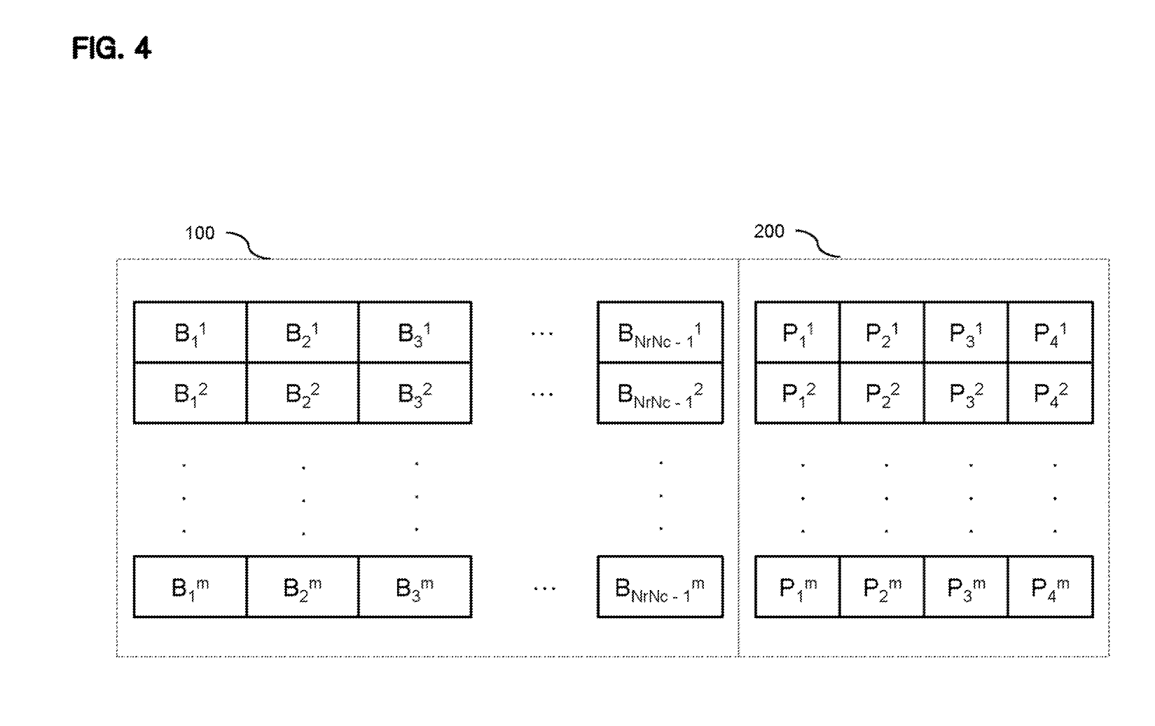

FIG. 4 exemplarily illustrates the first parity 200 generated by applying the RS code to the page 100 divided into the sub-message blocks 111 shown in FIG. 3.

The encoding operation through the RS code may be performed on a row basis of the sub-message blocks 111. As a result of the encoding operation through the RS code, four parities P₁ⁱ to P₄ⁱ (1≦i≦m) may be generated for each row. The four parities may be related to the number of pages to which the external code or the RS code is applied. The first parity 200 illustrated in FIG. 4 may be generated for each page.

Referring back to FIG. 1, the encoding method may generate a second parity 300 by performing an XOR operation on the first parities 200 generated for the respective pages at step S130. The relation between the second parity (P′ⱼⁱ) and the first parity (Pⱼⁱ) may be defined as in Equation 2 below.

P′ⱼⁱ=(Pⱼⁱ)_{page1}⊕(Pⱼⁱ)_{page2}⊕(Pⱼⁱ)_{page3}⊕(Pⱼⁱ)_{page4}(1≦i≦m,1≦j≦4) [Equation 2]

As shown in Equation 2, the second parity (P′ⱼⁱ) for the j-th position of the i-th sub-message block 111 in the message blocks 110 of the first to fourth page messages 100, may be generated on the basis of the first parities (Pⱼⁱ) of the corresponding j-th position of the corresponding i-th sub-message block 111 in the message blocks 110 of each of the first to fourth page messages 100. This means that all of the first to fourth page messages 100, and thus first to fourth symbols S₁ to S₄, which will later be discussed in detail, may relate to one another through the second parity (P′ⱼⁱ).

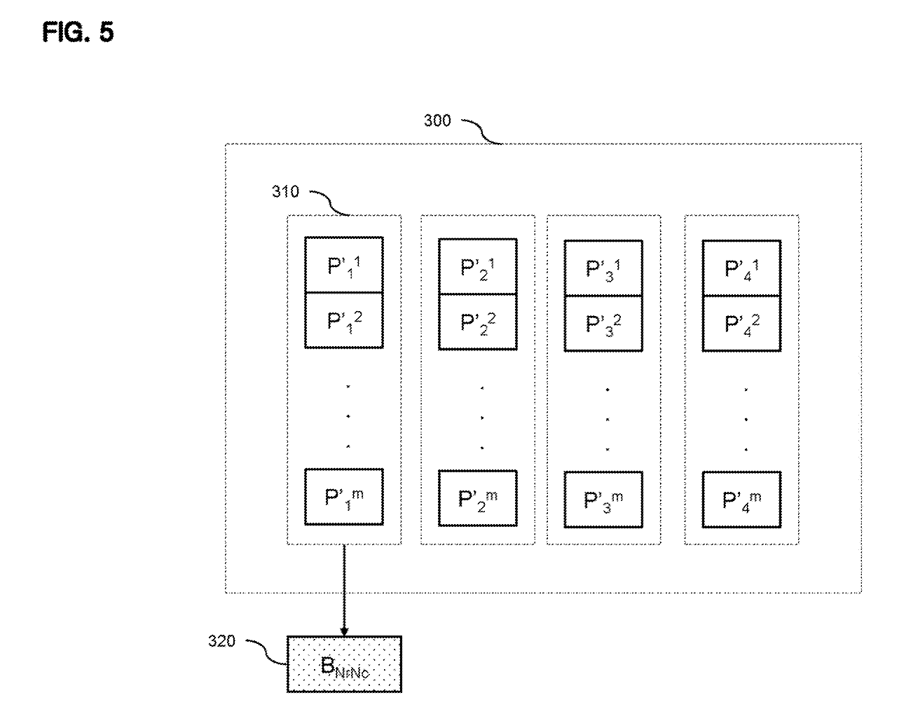

FIG. 5 exemplarily illustrates the second parity 300.

The second parity 300 may be divided into four parity groups 310 as illustrated in FIG. 5, and each of the parity groups 310 may be merged into a single parity block 320, thereby generating 4 parity blocks 320 in total for each of the first to fourth page messages 110.

In the present embodiment, four page messages 100 may be encoded through the external code or the RS code to acquire a total four first parities 200. An XOR operation may be performed on the first parities 200 to acquire a total of four second parities 300, and each of the second parities 300 may be divided into four parity blocks 320.

In another embodiment, one operation message may be generated by performing an XOR operation on message blocks 110 in the same position for four page messages 100, and be encoded through the external code or the RS code to generate a parity, and the parity may be divided into four parity blocks.

Referring back to FIG. 1, one of the four parity blocks 320 and the message blocks 110 may be combined to form one page data at step S130. The size of the parity block 320 may be designed such that the message blocks 110 may accept the size of the parity block 320.

Then, the encoding method may encode the four page data through the BC-BCH code or the internal code at step S140.

In the description, the number of required parity blocks is exemplarily set to 4 because the error correction ability of the RS code is designed for units of 2. The error correction ability of the external code or the RS code, and thus the number of required parity blocks and the number of pages protected by the external code or the RS code, may vary according to design.

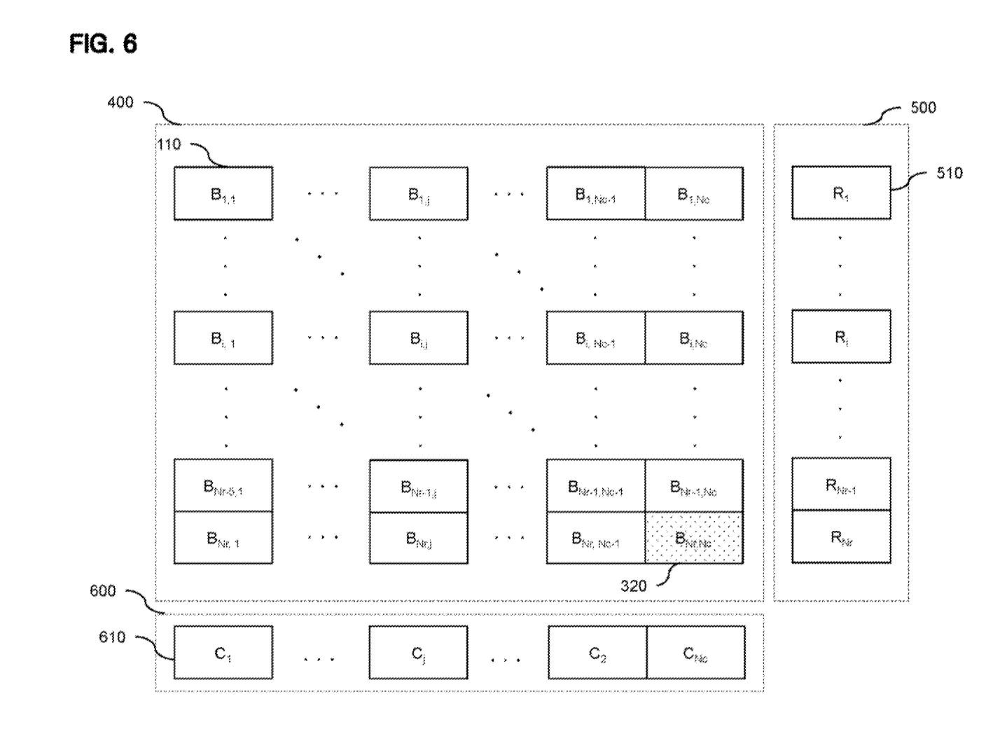

FIG. 6 is a diagram illustrating an example in which the BC-BCH code is applied to the page data 400.

In FIG. 6, each page data 400 may include (Nr×Nc) blocks including (Nr×Nc−1) message blocks 110 and a single parity block 320.

The (Nr×Nc) blocks may be arranged in rows and columns, and a row code 510 and a column code 610 may be generated for each of the Nr rows and each of the Nc columns.

The page data 400, a row code block 500, and a column code block 600 may be combined to form a symbol S.

As described above, the single symbol may include single page data 400 representing the page message 100 comprising the 4 message blocks 110, the 4 external parities (parity blocks) 200, which are formed by the external code or the RS code and represented by the four parity blocks 320, and the internal parity formed by the internal code or the BC-BCH code (row code and column code). Therefore, the page message 100 may be doubly protected by the external parity and the internal parity.

Hereafter, a decoding method in accordance with an embodiment of the present invention will be described.

Hereafter, first to fourth pages may correspond to first to fourth symbols to be read, respectively.

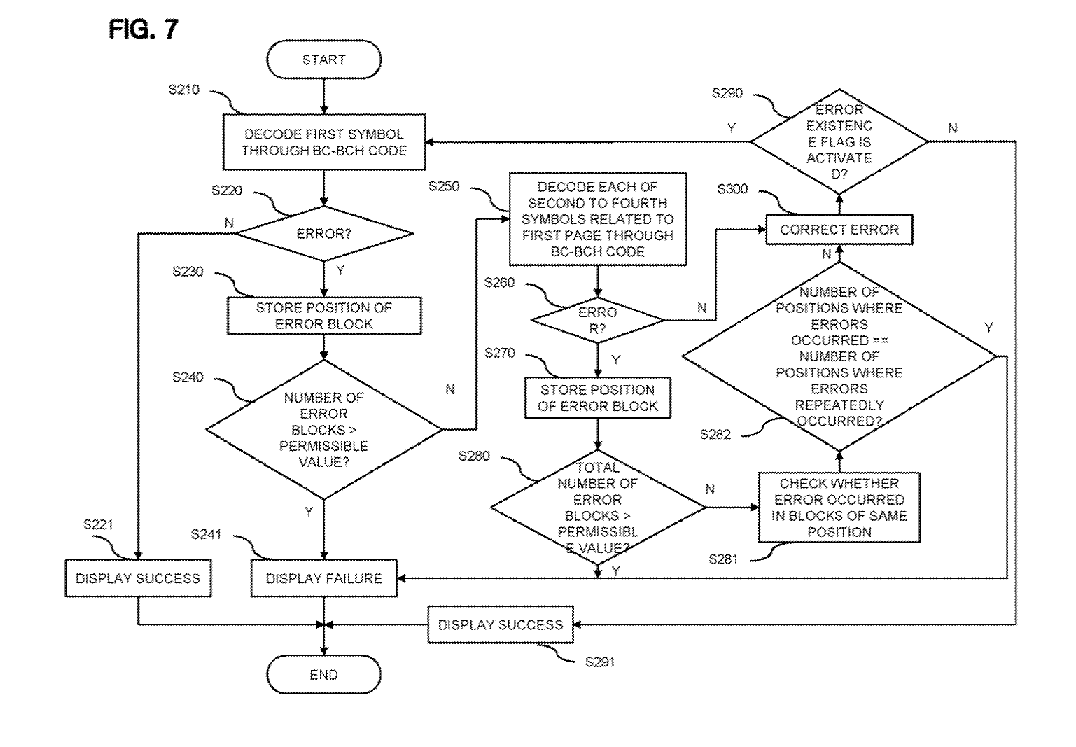

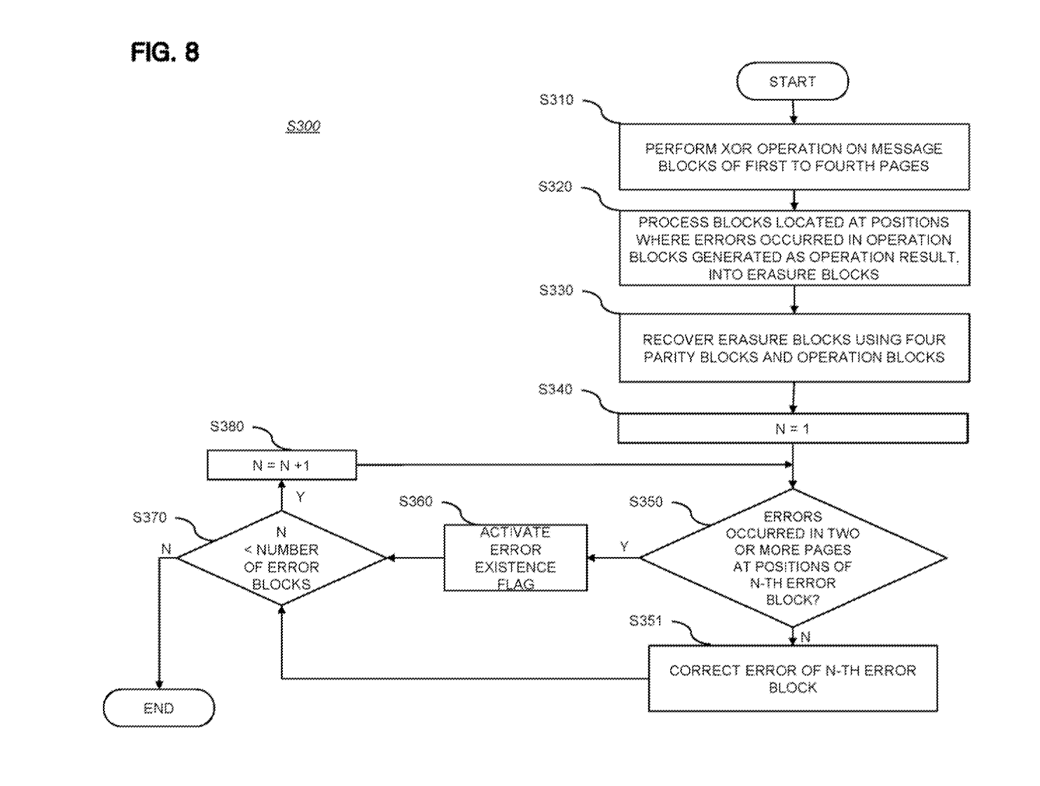

FIGS. 7 and 8 are flowcharts illustrating a decoding method in accordance with an embodiment of the present invention.

First, the decoding method may read the first symbol, and decode the read first symbol through a BC-BCH code at step S210.

The decoding method may determine whether an error occurred during the decoding operation at step S220. When no error occurs, the decoding method may end with decoding success at step S221. The error at step S220 may not be corrected by the BC-BCH code.

When an error occurs during the decoding operation, the position of a message block including the error may be stored at step S230. When the decoding operation is performed through the BC-BCH code, a row and column, at which the error occurs, may be specified in the row code 500 and the column code 600 to indicate the position of the message block including the error.

Then, the decoding method may determine whether the number of blocks in which an error occurred exceeds a permissible value at step S240.

The permissible value may indicate the maximum number of message blocks that include an error and can be corrected through the RS code. The permissible value may vary according to design of the RS code.

When the number of error blocks exceeds the permissible value, the decoding method may end with decoding failure at step S241.

When the number of error blocks does not exceed the permissible value, second to fourth symbols related to the first symbol may be decoded through the BC-BCH code at step S250.

When no errors occurs, the procedure may proceed to error correction step S300, and when errors occurs, the decoding method may store the positions of the blocks that have errors at step S270.

The error correction step S300 will be described below in detail with reference to FIG. 8. The error may not be corrected through the BC-BCH code.

Then, the decoding method may determine whether the total number of message blocks, in which errors occurred while the first to fourth symbols are decoded, exceeds the permissible value at step S280. The permissible value of step S280 may be the same as the permissible value at step S240.

When the total number of message blocks including the error exceeds the permissible value, the errors cannot be corrected. Thus, the decoding method may end with the decoding failure at step S241.

When the total number of message blocks including the error does not exceed the permissible value, the procedure may proceed to step S281.

At step S281, the decoding method may determine whether the message blocks including errors 110 are located at the same position over two or more pages using the position information of the message blocks including the error. For example, when an error occurred in a first message block 110 of the first page data 400 and an error occurred in a first message block 110 of the second page data 400, the decoding method may determine that the errors in message blocks are located at the same position.

Then, the decoding method may determine whether the number of positions where errors occur is equal to the number of positions where errors repeatedly occur, at step S282. At step S282, the method may determine whether or not every message block including errors occurs at the same position over two or more pages.

When the number of positions where errors occur is equal to the number of positions where errors repeatedly occur, this means that the errors cannot be corrected at the error correction step S300, and the decoding method may end with the decoding failure at step S241.

On the other hand, when the number of positions where errors occur is different from the number of positions where errors repeatedly occur, the procedure may proceed to the error correction step S300.

At the error correction step S300, when all the error blocks are corrected, an error existence flag may be deactivated, and when error blocks remain, the error existence flag may be activated. The error correction step S300 will be described below in more detail.

After the error correction step S300, the decoding method may determine whether the error existence flag is activated at step S290. When the error existence flag is deactivated, it may indicate that all the error blocks are corrected. Thus, the decoding method may end with the decoding success at step S291.

When the error existence flag is activated, the decoding method may return to step S210. In this case, however, the decoding method may not decode the entire first symbol, but may reflect the error correction result at step S300 into the first symbol to update the first page data 400, correct errors of the updated first page data 400 using the internal code, and update the error information.

Thus, although the message blocks still include errors after the error correction step S300 is performed, the decoding method may perform step S210 again to correct all the errors existing in the first page data 400. In this case, the decoding method may end with the decoding success at step S221.

FIG. 8 is a flowchart illustrating the error correction step S300 of FIG. 7.

As described above, the four parity blocks 320 included in each of the first to fourth page data 400 may be obtained by dividing the second parity 300, which is generated by performing an XOR operation on the first parities 200 on a page basis or in each of the first to fourth page data 400. The first parity 200 in each of the first to fourth page data 400 may be generated by encoding the message blocks 110 included in each of the first to fourth page data 400 through the RS code.

Mathematically, the encoding operation through the RS code (step S120 described above with reference to FIGS. 1 to 4) and the XOR operation by the unit of access or a single page (step S130 described above with reference to FIGS. 1 to 5) may be exchangeable. This may indicate that the parity generated through encoding of operation message blocks, which are obtained through the XOR operation on the message blocks 110 of the first to fourth page 100 by the unit of access or single page, through the RS code may be the same as the second parity 300 of the first to fourth page messages obtained through the XOR operation on the first parities 200 of the first to fourth page messages generated through encoding of the first to fourth page messages 100 through the RS code.

Referring to FIG. 8, the decoding method may perform an XOR operation on the message blocks 110 of the first to fourth page 100, which are obtained by decoding the first to fourth symbols through the BC-BCH code through steps S210 to S282, described above with reference to FIG. 7, by the unit of access or single page, and generate the operation message blocks at step S310.

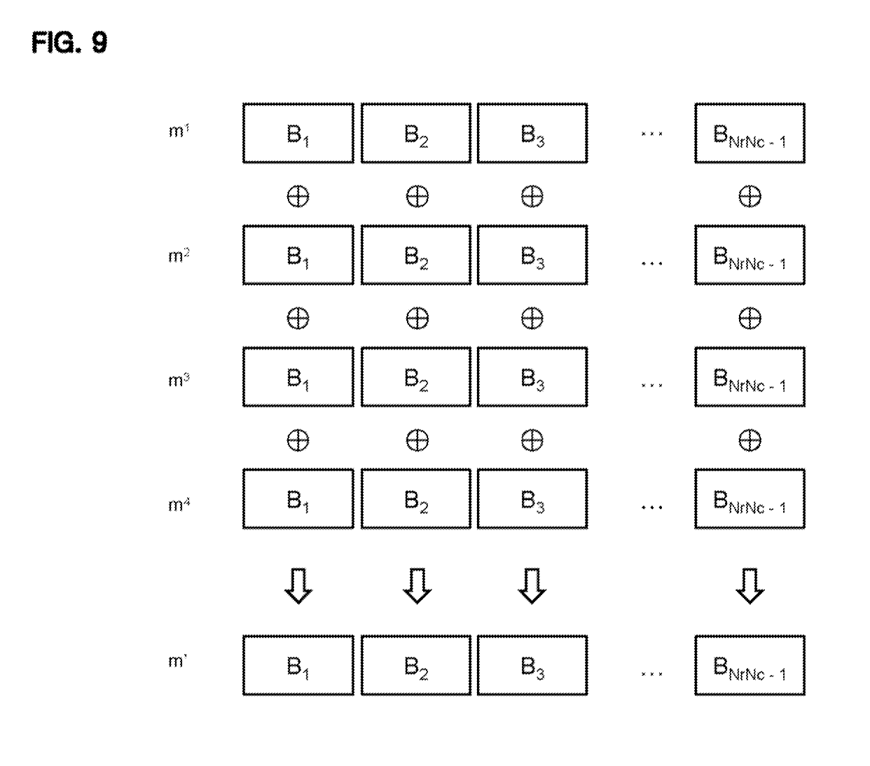

FIG. 9 is a diagram illustrating the operation message blocks generated through step S310 shown in FIG. 8.

FIG. 9 illustrates the XOR operation on corresponding message blocks of page messages m1 to m4, which are included in the first to fourth page data 400 obtained by decoding the first to fourth symbols, by the unit of access or single page, and the operation message m′ having the operation message blocks as the result of the XOR operation.

Referring back to FIG. 8, the decoding method may process all of the operation message blocks corresponding to positions where errors occurs among the operation message blocks of the operation message m′, to be unknown blocks at step S320. The unknown block may have an unknown bit value.

Then, the decoding method may recover the unknown blocks using the operation message m′ and four parity blocks 320, which are obtained by decoding the first to fourth symbols through the BC-BCH code, at step S330.

As described above, since the encoding operation through the RS code (step S120 described above with reference to FIGS. 1 to 4) and the XOR operation by the unit of access or single page (step S130 described above with reference to FIGS. 1 to 5) are exchangeable, a result obtained by encoding the operation message m′ through the RS code may be the same as the second parity 300 of the first to fourth page messages, which is obtained through the XOR operation on the first parities 200 of the first to fourth page messages generated through encoding of the first to fourth page messages 100 through the RS code, and thus the four parity blocks 320. Thus, the unknown bit values of the respective unknown blocks may be recovered by decoding the operation message m′ and the four parity blocks 320 through the RS code.

In the above-described embodiment, the unknown blocks may be individually recovered at an unknown block level by decoding the operation message m′ and the four parity blocks 320 through the RS code based on the information on the position of the individual unknown block of step S320.

In another exemplary embodiment, the unknown blocks may be recovered at an operation message m′ level by decoding the operation message m′ and the four parity blocks 320 through the RS code without the information on the position of the unknown block of step S320 and without individual recovery of the unknown blocks.

Thus, the unknown bit values of the unknown blocks in the operation message m′ may be recovered. In the following steps, the recovered operation message m′ may be used to recover message blocks having errors in the respective page messages m1 to m4, which are included in the first to fourth page data 400 obtained by decoding the first to fourth symbols.

For this operation, an index N indicating the number of positions of message block 110 including the errors in the first to fourth page messages 100 may be set to 1 at step S340.

Then, the decoding method may check whether the position of an N-th message block 110 including the errors corresponds to the position where the errors repeatedly occur in two or more of the first to fourth pages 100 at step S350.

When the position of the N-th message block 110 including the errors corresponds to the position where the errors repeatedly occurs, the N-th message block 110 cannot be corrected. Thus, the decoding method may activate the error existence flag at step S360, and proceed to the next step S370.

When the position of the N-th message block 110 including the errors does not correspond to the position where the errors repeatedly occur, the N-th message block 110 may be corrected at step S351. For example, when the N-th message block 110 in the first page 100 includes errors, the N-th message block 110 in the first page 100 may be corrected through Equation 3 below.

(B_{N})_{page1}=S_{N}⊕(B_{N})_{page2}⊕(B_{N})_{page3}⊕(B_{N})_{page4} [Equation 3]

In Equation 3, S_{N} represents a corresponding N-th operation message block in the operation message m′, and B_{N} represents a corresponding N-th message block 110 in each of the first to fourth page messages 100.

Then, the decoding method may repeat the above-described steps on all error blocks and end the procedure at steps S350, S351, and S360.

When the step S360 was performed one or more times during this iterative process, it may indicate that there exists a message block 110 in which errors repeatedly occur at a specific position and thus cannot be corrected.

In this case, the step S210 and the subsequent steps in FIG. 7 may be repeated.

While the steps are repeated, the result obtained by correcting errors at step S351 of FIG. 8 may be reflected into the following repetitive steps. Thus, while the step S210 of FIG. 7 is performed in the following repetitive steps, the message block 110 having the errors within the page messages 100, which cannot be corrected in the current repetitive steps, may be corrected through the internal code or the BC-BCH code, and the decoding may be successfully ended.

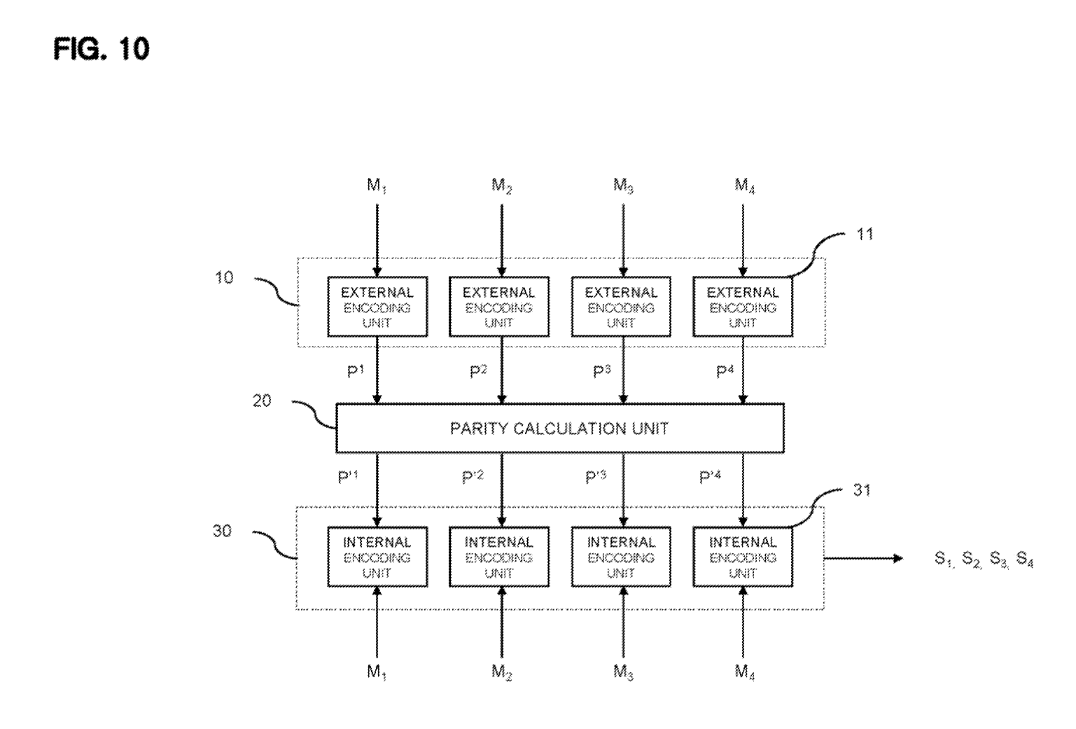

FIG. 10 is a block diagram illustrating an encoding device in accordance with an embodiment of the present invention.

The encoding device in accordance with the embodiment of the present invention may include an external encoder 10, a parity calculation unit 20, and an internal encoder 30.

The external encoder 110 may encode the first to fourth page messages M₁ to M₄ using an external code, for example, the RS code, and generate first parities P¹ to P⁴ corresponding to the respective page messages.

As described with reference to FIGS. 3 and 4, each of the first parities P¹ to P⁴ may be divided into four sub-parities.

In the present embodiment, the external encoder 10 may include four external encoding units 11 corresponding to the page messages M₁ to M₄, respectively.

In another embodiment, the external encoder 10 may include one external encoding unit 11 for sequentially encoding the first to fourth page messages M₁ to M₄ and sequentially output the first parities P¹ to P⁴.

The parity calculation unit 20 may perform an XOR operation on the first parities P¹ to P⁴ on a page basis as expressed by Equation 2, and generate four parity blocks P′¹ to P′⁴.

The internal encoder 30 may combine any one of the four parity blocks P′¹ to P′⁴ with any one of the four page messages M₁ to M₄, and generate total four page data. Furthermore, the internal encoder 30 may encode the page data by applying the internal code, for example, the BC-BCH code to the page data, and generate four symbols S₁ to S₄.

In the present embodiment, the internal encoder 30 may include four internal encoding units 31. Each of the four internal encoding units 31 may combine one of the page messages M₁ to M₄ and one of the parity blocks P′¹ to P′⁴ into a single page data, encode the page data through the internal code, and output the corresponding symbol. This process has been described above with reference to FIG. 6.

In another embodiment, the internal encoder 30 may include one internal encoding unit 31 for sequentially performing four encoding operations, and sequentially output four symbols S₁ to S₄.

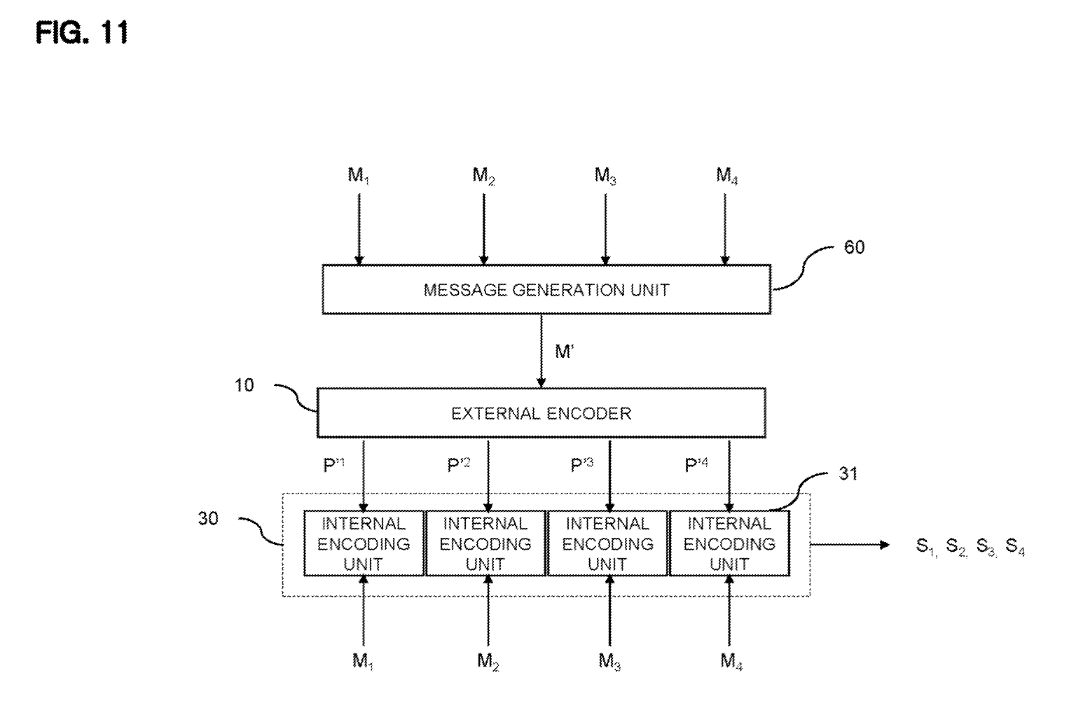

FIG. 11 is a block diagram illustrating an encoding device in accordance with another embodiment of the present invention.

The encoding device of FIG. 11 may include a message generation unit 60, an external encoding unit 11, and an internal encoder 30.

The message generation unit 60 may perform an XOR operation on the message blocks 110 in the same position in each of the four page messages M₁ to M₄, and generate an operation message M′ including the operation message blocks, as described with reference to FIG. 9.

The external encoding unit 11 may generate the second parity 300 of the page messages M₁ to M₄ by encoding the operation message M′ through the external code or the RS code, and divide the parity into the four parity blocks P′¹ to P′⁴.

The internal encoder 30 may be the same as the Internal encoder 30 described above with reference to FIG. 10.

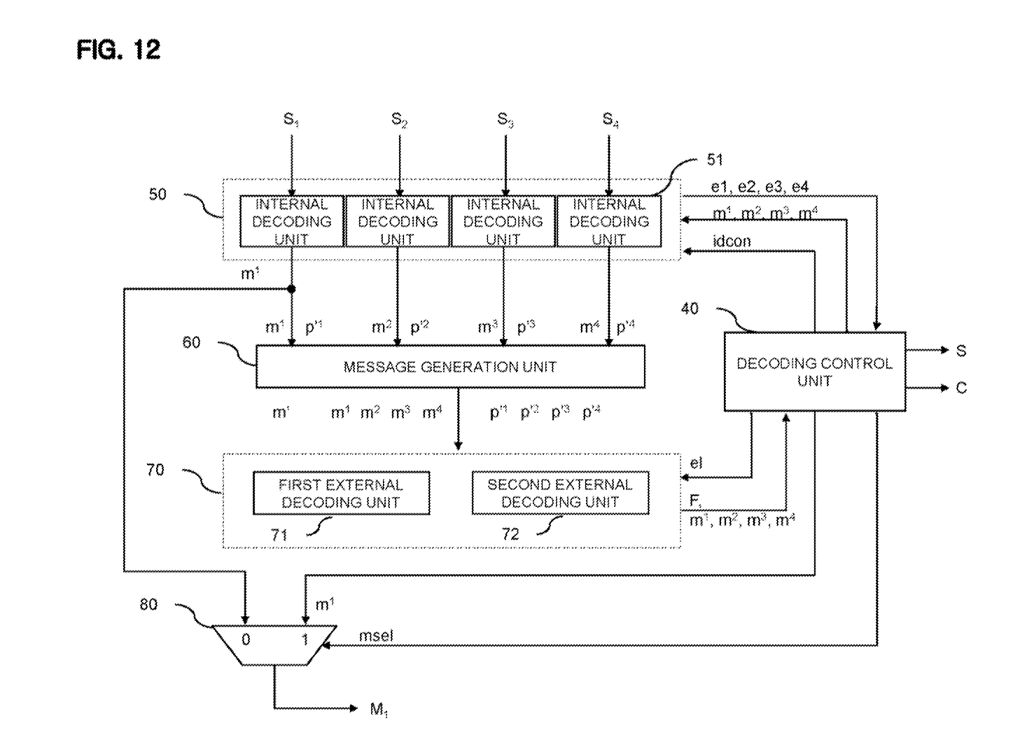

FIG. 12 is a block diagram illustrating a decoding device in accordance with an embodiment of the present invention.

It is assumed that a first symbol S₁ among the first to fourth symbols S₁ to S₄ is to be read, and the rest of the first to fourth symbols S₁ to S₄ are related to the first symbol Sₜ, as described above with reference to Equation 2.

The decoding device in accordance with the embodiment of the present invention may include a decoding control unit 40, an internal decoder 50, a message generation unit 60, an external decoder 780, and a message selection unit 80.

The decoding control unit 40 may perform the decoding operation described with reference to FIGS. 7 and 8. For this operation, the decoding control unit 70 may control the internal decoder 50, the external decoder 70, and the message selection unit 80.

The decoding control unit 40 may activate and output a completion flag C when the decoding operation is completed, and activate and output a success flag S when the decoding operation is successfully performed.

The internal decoder 50 may include four internal decoding units 51. The internal decoding units 51 may decode the first to fourth symbols S₁ to S₄ using the internal code, for example, the BC-BCH code, respectively. When an uncorrectable error occurs, the respective internal decoding units 51 may provide error information e1 to e4 to the decoding control unit 40. The error information e1 to e4 may indicate the position of the error.

In another embodiment, the internal decoder 50 may include one internal decoding unit 51, and sequentially decode the first to fourth symbols S₁ to S₄.

When no errors occur during decoding of the first symbol S₁ through the internal code, the decoding control unit 40 may deactivate a message select signal msel based on the error information e1, control the message selection unit 80 to select the first page message m1 decoded by the internal decoding unit 51 as an output message M1, and end the decoding operation.

When errors occurred during decoding of the first symbol S₁ through the Internal code, the decoding control unit 40 may check the positions and the numbers of the message blocks where the errors occurred, by referring to the error information e1.

When the number of message blocks in which the errors occurred exceeds the permissible value, the decoding control unit 40 may deactivate the success flag S, activate the completion flag C, and end the decoding operation as the decoding failure.

When the number of the message blocks having errors falls within the permissible value, the decoding control unit 40 may provide an internal decoding unit control signal idcon to control the internal decoder 50 to decode the second to fourth symbols S₂ to S₄ related to the first symbol S₁.

When errors occur during decoding of the second to fourth symbols S₂ to S₄, the decoding control unit 40 may check the positions and the number of message blocks in which errors occur by referring to the error information e2 to e4.

When the total number of message blocks having errors during the decoding of the first to fourth symbols S₁ to S₄,=, exceeds the permissible value, the decoding control unit 40 may deactivate the success flag S, activate the completion block C, and end the decoding operation as a decoding failure.

The internal decoder 50 may output the page messages m¹ to m⁴ and the parity blocks p′¹ and p′⁴ as a result of the internal decoding.

The message generation unit 60 may perform an XOR operation on the message blocks in the same position for each of the page messages m¹ to m⁴ by the unit of access or single page, and output the operation message m′. The operation of the message generation unit 60 has been described with reference to FIG. 9.

The external decoder 70 may include a first external decoding unit 71 and a second external decoding unit 72.

The first external decoding unit 71 may recover the operation message m′, and the second external decoding unit 72 may correct the message blocks including the errors using the recovered operation message m′ and the page messages m¹ to m⁴.

The decoding control unit 40 may provide the position information el of the message blocks where the errors occur to the external decoder 70.

The first external decoding unit 71 may process all of the operation message blocks corresponding to the positions where the errors occur among the operation message blocks in the operation message m′, to be the unknown blocks. Then, the first external decoding unit 71 may recover the unknown blocks by applying the external code to the operation message m′ and the parity blocks p′¹ to p′⁴, which are obtained by internally decoding the first to fourth symbols S₁ to S₄ through the BC-BCH code.

In the above-described embodiment, the unknown blocks may be individually recovered at an unknown block level by decoding the operation message m′ and the four parity blocks 320 through the RS code based on the information el on the position of the individual unknown block of step S320. In another exemplary embodiment, the unknown blocks may be recovered at an operation message m′ level by decoding the operation message m′ and the four parity blocks 320 through the RS code without the information el on the position of the unknown block of step S320 and without individual recovery of the unknown blocks.

Thus, the unknown bit values of the unknown blocks in the operation message m′ may be recovered. In the following process, the recovered operation message m′ may be used to recover message blocks having errors in the respective page messages m¹ to m⁴, which are included in the first to fourth page data 400 obtained by decoding the first to fourth symbols S1 to S4.

The second external decoding unit 72 may recover the message blocks having errors in the page messages m′ to m⁴ using the recovered operation message m′. The message blocks of the page messages m¹ to m⁴ may be sequentially recovered through the operation of Equation 3.

At this time, when the number of positions of blocks where errors occur is equal to the number of positions of blocks where errors repeatedly occur, which means all of the errors are occurring at the same positions of blocks over two or more pages, the second external decoding unit 72 may not recover the message blocks having the errors, may activate a flag F, and may recover the next message block.

The second external decoding unit 72 may provide the flag F and the page messages m¹ to m⁴, the errors of which are recovered, to the decoding control unit 40.

When the flag F is deactivated, the decoding control unit 40 may activate the success flag S and the completion flag C, and end the decoding operation with decoding success. At this time, the decoding control unit 40 may activate the message select signal msel to output the decoded message m¹ as the output message M₁.

When the flag F is activated, the decoding control unit 40 may control the above-described operation to be repeated. At this time, the decoding control unit 40 may provide the page messages m¹ to m⁴ outputted from the second external decoding unit 72 to the internal decoder 50. The respective internal decoding units 51 may update the page messages m¹ to m⁴ obtained through the previous decoding operation. When correctable errors exist in the updated messages, the internal decoding units 51 may correct the errors and update the error information e1 to e4.

The following operations may be repeated as described above. The decoding control unit 40 may limit the number of repetitions to a predetermined threshold value. When the number of repetitions exceeds the threshold value, the decoding control unit 40 may deactivate the success flag S, activate the completion flag C, and end the operation with a decoding failure.

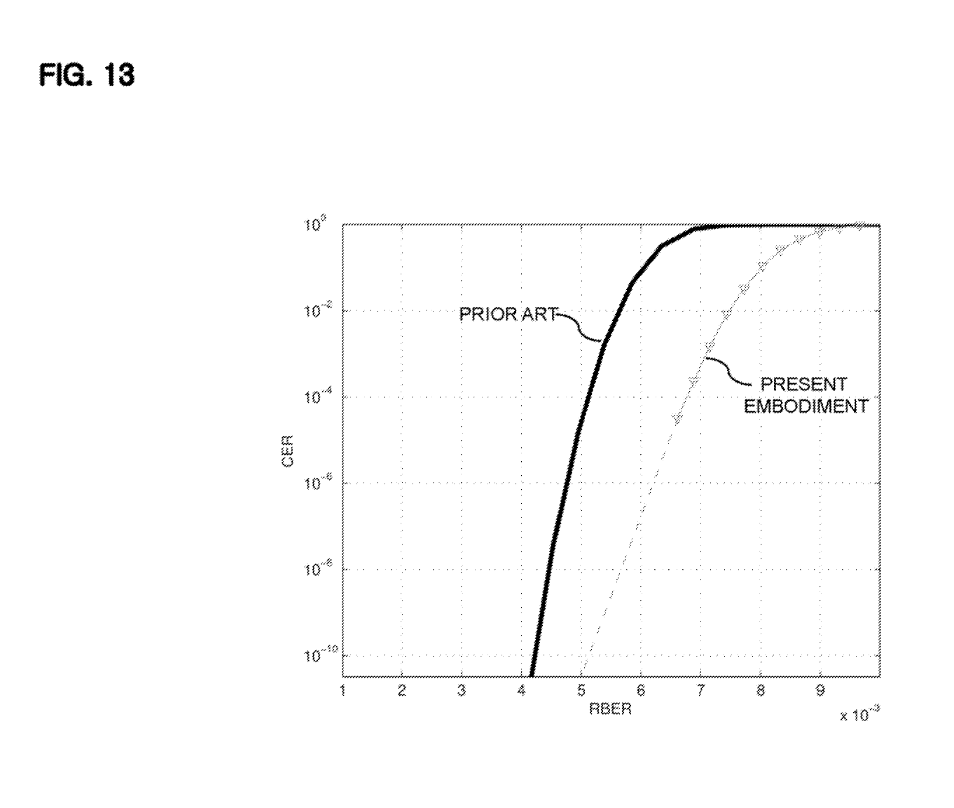

FIG. 13 is a simulation graph illustrating a result in accordance with an embodiment of the present invention illustrating an error occurrence rate in a memory cell array in which a page of 4 kB is the unit of access.

The graph of “PRIOR ART” indicates the coding case of the page of 4 kB only through the BCH code, and the graph of “PRESENT EMBODIMENT” indicates the coding case of the page of 4 kB through the BC-BCH code as the internal code and the RS code as the external code.

The horizontal axis of the graph indicates a raw bit error rate (BER) which is a basic error rate of a memory cell, and the vertical axis of the graph may indicate a codeword error rate (CER) which is an error rate when one page is read. In the graph of “PRESENT EMBODIMENT”, the solid line indicates a result obtained through a simulation, and the dotted line indicates a result obtained by extrapolating the simulation result.

The graph may indicate that the present embodiment has much better performance than the conventional method, when the same raw BER is applied. For example, when the raw BER is 6.5×10⁻³, it is expected that the CER of the present embodiment will decrease to about 1/1000 of the CER of the conventional method, and when the raw BER is 5×10⁻³, the CER of the present embodiment will decrease to about 1/1000000 of the CER of the conventional method.

In accordance with the embodiments of the present invention, a coding method and device may provide protection on a message by a single unit of access as well as by a plurality of units of access, thereby improving message protection.

Although various embodiments have been described for illustrative purposes, it will be apparent to those skilled in the art that various changes and modifications may be made without departing from the spirit and scope of the invention as defined in the following claims.

What is claimed is:

1. An encoding method comprising:
generating a plurality of parity blocks by encoding a plurality of messages through an external code;
generating a plurality of message data by combining the plurality of messages and the plurality of parity blocks; and
generating a plurality of symbols by encoding each of the plurality of message data through an internal code.

2. The encoding method of claim 1, wherein the generating of the plurality of parity blocks comprises:
generating a plurality of first parities for each of the plurality of messages by encoding each of the plurality of messages through the external code;
generating a second parity by logically combining the plurality of first parities; and
generating the plurality of parity blocks by dividing the second parity.

3. The encoding method of claim 1, wherein the generating of the plurality of parity blocks comprises:
generating an operation message by logically combining the plurality of messages;
generating a parity by encoding the operation message through the external code; and
generating the plurality of parity blocks by dividing the parity.

4. The encoding method of claim 2, wherein each of the plurality of message data includes one of the plurality of messages and one of the plurality of parity blocks.

5. The encoding method of claim 4, wherein each of the plurality of messages includes a plurality of message blocks.

6. The encoding method of claim 5, wherein the generating the plurality of symbols generate position code, which indicates positions of one or more of the plurality of message blocks including an error, in each of the plurality of symbols.

7. A decoding method for decoding a first symbol including a message, an internal code and an external code, comprising:
decoding the first symbol through an internal code;
decoding a second symbol through the internal code when the first symbol has an error; and
correcting errors that the first and second symbols have through an external code.

8. The decoding method of claim 7,
wherein the correcting of the errors comprises:
generating an operation message by logically combining first and second messages, wherein the first message is generated by decoding the first symbol and the second message generated by decoding the second symbol;
recovering the operation message using the external parity; and
correcting errors of the first and second messages using the recovered operation message and the first and second messages.

9. The decoding method of claim 8, wherein the correcting of the errors further comprises: making one or more blocks of the operation message unknown, wherein a position of a unknown block corresponds to a position where the errors occurred at the first message and the second message, and the correcting the errors comprises recovering the unknown block of the operation message.

10. The decoding method of claim 8, when uncorrected errors remain in the first and second symbols after the correcting of the errors, further comprising:
updating the external parity and the first and second messages using a result of the correcting of the errors; and
repeating the decoding of the second symbol and the correcting of the errors using the updated external parity and the updated first and second messages.

11. An encoding device comprising:
a parity generation unit suitable for generating a plurality of parity blocks by encoding a plurality of messages through an external code; and
an internal encoder suitable for generating a plurality of message data by combining the plurality of messages and the plurality of parity blocks, and generating a plurality of symbols by encoding each of the plurality of message data through an internal code.

12. The encoding device of claim 11, wherein the parity generation unit comprises:
an external encoder suitable for generating a plurality of first parities for each of the plurality of messages by encoding each of the plurality of messages through the external node; and
a parity calculation unit suitable for generating a second parity by logically combining the plurality of first parities, and generating the plurality of parity blocks by dividing the second parity.

13. The encoding device of claim 11, wherein the parity generation unit comprises:
a message generation unit suitable for generating an operation message by logically combining the plurality of messages; and
an external encoder suitable for generating a parity by encoding the operation message through the external code, and generating the plurality of parity blocks by dividing the parity.

14. A decoding device for decoding a first symbol including an external code, comprising:
an internal decoder suitable for decoding the first symbol and a second symbol through an internal code;
a message generation unit suitable for generating an operation message by logically combining first and second messages, wherein the first message is generated through decoding of the first symbol and the second message is generated through the decoding of the second symbol; and
an external decoder suitable for correcting errors that the first and second messages of the first and second symbols have through the external code.

15. The decoding device of claim 14, wherein the external decoder comprises:
a first external decoding unit suitable for recovering the operation message through the external code; and
a second external decoding unit suitable for correcting errors of the first and second messages using the recovered operation message.

16. The decoding device of claim 15,
wherein the operation message has one or more errors at one or more positions corresponding to the positions of the errors of the first and second symbols in the first and second messages, and
wherein the first external decoding unit recovers the errors of the operation message.

17. The decoding device of claim 14, further comprising a decoding control unit suitable for controlling the internal decoder and the external decoder.

18. The decoding device of claim 17,
wherein the external decoder activates an error flag when an uncorrected error remains in the first and second symbols,
wherein the decoding control unit provides the first and second messages, which are corrected by the external decoder, to the internal decoder when the error flag is activated, and
wherein the internal decoder corrects the first and second messages provided from the decoding control unit according to the internal code.

19. The decoding device of claim 18, wherein the external decoder activates the error flag when errors occur at the same positions of the first and second messages.

20. The decoding device of claim 18, further comprising a message selection unit suitable for selecting and outputting one of the first message decoded by the internal decoder and the first message decoded by the external decoder according to control of the decoding control unit.
